(19) United States
(12) Patent Application Publication
(10) Pub. No.: US 2023/0164922 A1
(43) Pub. Date: May 25, 2023

(54) METHOD FOR PROTECTING THE COMPONENTS OF A PRINTED CIRCUIT BOARD

(71) Applicant: ZF Friedrichshafen AG, Friedrichshafen (DE)

(72) Inventors: Tobias OPPAWSKY, Oberteuringen (DE); Manuel SCHWAB, Friedrichshafen (DE); Frank SCHUHMACHER, Ravensburg (DE); Kevin HEIMBURGER, Engen (DE); David ZÜLKE, Weingarten (DE); Felix RIETSCH, Rehau (DE); Jürgen PORSCH, Speichersdorf (DE); Roman HUFF, Ravensburg (DE); Marco IGEL, Bodnegg (DE); Ulrich SCHMITZ, Auerbach (DE)

(73) Assignee: ZF Friedrichshafen AG, Friedrichshafen (DE)

(21) Appl. No.: 17/992,242

(22) Filed: Nov. 22, 2022

(30) Foreign Application Priority Data
Nov. 23, 2021 (DE) 102021213165.4

(51) Int. Cl. H05K 3/28

(52) U.S. Cl. CPC H05K 3/28

(57) ABSTRACT

A method for protecting the components of a printed circuit board which is loaded with specified components includes setting up a coating barrier in the form of an edge around coating exclusion regions of a printed circuit board into which a protective coating does not penetrate, and providing the printed circuit board with the protective coating at specified regions thereof. A printed circuit board produced by the method is also disclosed.

### CROSS-REFERENCE TO RELATED APPLICATIONS

This application claims priority from German Application No. DE 10 2021 213 165.4, filed on Nov. 23, 2021, the entirety of which is hereby fully incorporated by reference herein.

### BACKGROUND AND SUMMARY

The present invention relates to a method for protecting the components of a printed circuit board, in particular for applications in the area of electromobility.

Electrical or electronic components are applied to printed circuit boards for example by soldering, such as SMD soldering, in a corresponding installation. These components must then be subsequently protected from external influences such as contamination by applying a protective coating.

Increasingly smaller contact spacings within individual components, for example in the case of microcontrollers, mean that increasingly greater requirements are demanded of the protection from residual contamination for all other components that are present on the printed circuit board, in order to prevent this aforementioned component from being damaged or adversely affected. It has not so far been possible to guarantee that the components are 100% free of residual contamination. Only the maximum size of particles occurring can be guaranteed. However, the maximum guaranteed size of particles is too large for most electronic components with a pin spacing of just a few hundred nanometers. Consequently, single particles can lead to shorting of the pins, with the result that the component, and with it possibly the entire system, is no longer fully functional. Such particles may even lead to complete failure.

The problem stated also applies to components of power-electronic drive converters, which are also known as inverters. In order to avoid these problems, in most drive inverters the printed circuit boards are coated. However, due to the coating tolerance or the characteristics of the coating, it may flow into coating exclusion regions. This leads to increased numbers of rejects in production. In order to counteract this, the dimensions of the printed circuit board must be increased in size, which inevitably leads to an undesired increase in size of the installation space and extra costs.

It is therefore an object of this invention to provide a method for protecting components of a printed circuit board by which the aforementioned problems are overcome. This object is achieved by the features of the independent patent claims. Advantageous refinements are the subject of the dependent claims.

Proposed is a method for protecting the components of a printed circuit board which is loaded with specified components and in a first step is provided with a protective coating at specified regions thereof, wherein the first step is preceded by an initial step in which a coating barrier in the form of an edge is set up around coating exclusion regions, into which the protective coating must not penetrate.

By providing an edge as a physical barrier between the region to be coated and the coating exclusion region, that is to say essentially the region in which components that are not to be coated are provided, both the numbers of rejects in production can be reduced and the transitional region between the region to be coated and the coating exclusion region can be reduced in size.

It is also provided that the coating barrier is produced by taking back a solder resist coating and/or taking back a copper layer of the printed circuit board. There are therefore three variants for creating the edge that stops the protective coating from penetrating into coating exclusion regions.

In all of the variants, material of the printed circuit board is processed in such a way that the edge is produced by the material.

It is also provided that the coating barrier is produced on the upper side and/or the underside of the printed circuit board. The method is therefore not restricted to only allowing one side of the printed circuit board to be provided with the coating barrier. If the printed circuit board is loaded with components on both sides or if specific through-holes must not be coated, it may be advisable to provide a coating barrier at specific regions on both sides.

It is also provided that coating exclusion regions are one or a combination of: specified regions around electronic components, connectors, pins, screwing areas, through-openings, production bearing surfaces. On printed circuit boards, specific regions must definitely be prevented from being provided with coating, for example because further processing must be performed thereafter, for example feeding contact pins through through-holes, etc. These regions are surrounded by the coating barrier.

Also provided is a printed circuit board which is loaded with specified components and is produced by the described method. Also provided are an inverter with the printed circuit board, an electronics module for controlling an electric drive of a vehicle, wherein the electronics module has an inverter, and also an electric drive with the electronics module and a vehicle with an electric drive with the electronics module.

Further features and advantages of the invention emerge from the following description of exemplary embodiments of the invention on the basis of the figures of the drawing, which show details according to the invention, and from the claims. The individual features may be realized in each case individually by themselves or as a plurality in any desired combination in a variant of the invention.

Preferred embodiments of the invention are explained in more detail below with reference to the appended drawing.

### BRIEF DESCRIPTION OF THE DRAWINGS

FIG. 1 shows a schematic view of a component arranged on a printed circuit board and having a coating layer according to the prior art.

FIGS. 2, 3, and 4 each show a schematic view of components surrounded by a coating barrier according to different embodiments of the present invention.

FIG. 5 shows a flow diagram of a method according to another embodiment of the present invention.

### DETAILED DESCRIPTION

In the following descriptions of the figures, the same elements or functions are provided with the same designations.

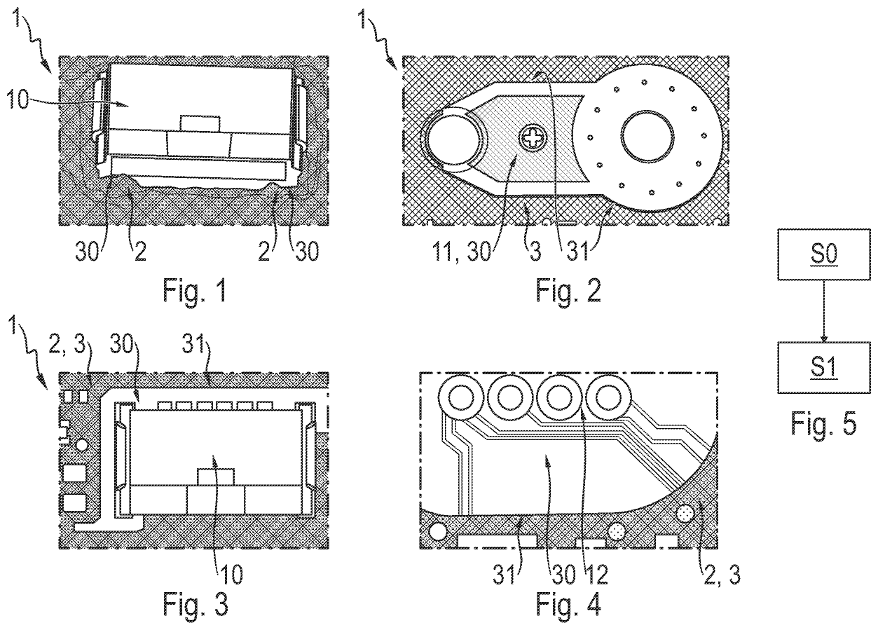

As already mentioned above, due to the coating tolerance or the characteristics of the protective coating 2, it may flow into coating exclusion regions 30, as shown in FIG. 1, and consequently lead to components being damaged, with the result that the printed circuit board 1 can no longer be used.

In order to avoid this, a coating barrier 31 is produced before the coating of the printed circuit board 1, to be precise before specific regions (coating exclusion regions 30) thereof. This protects the coating exclusion regions 30, and consequently the components 10-12 to be protected, from uncontrolled inflow or penetration of the protective coating 2. In this way the protective coating 2 is prevented from flowing into regions (coating exclusion regions 30) that are not intended to be covered by the protective coating 2 on account of its viscosity.

Such coating exclusion regions 30 are for example specified regions around electronic components 10 such as microcontrollers or sensors, connectors, pins, screwing areas, through-openings 12, production bearing surfaces 11, etc.

As shown in FIGS. 2 to 4, the coating barrier 31 is an actual, mechanical barrier in the form of an edge. This serves as a wetting obstacle, at which the protective coating 2 gets held up as a result of cohesive forces or surface tension, that is to say can no longer flow on account of physical conditions. In FIGS. 3 and 4, the protective coating 2 applied to the solder resist coating 3 is indicated in the drawing. In FIG. 2, a protective coating 2 has not yet been applied, only the coating barrier 31 has been created.

Providing the edge as a coating barrier 31 is advantageous not only because damage due to shorting or clogging of openings etc. as a result of the inflow of the protective coating 2 to the components 10-12 that are actually to be protected from this can be prevented. What is more, the transitional region between the coating region (region to be coated of the printed circuit board 1) and the coating exclusion region 30 can also be reduced, and consequently a higher packing density can be achieved.

The edge of the coating barrier 31 is produced by the solder resist coating 3 that is present on the printed circuit board 1 and/or the copper layer of the printed circuit board 1 that is either exposed or lies under the solder resist coating 3 being taken back to a specified distance, i.e. removed by corresponding methods such as etching. In FIG. 2, only the solder resist coating 3 has been removed, whereas in FIGS. 3 and 4 the copper layer has likewise been removed.

The distance of the edge from the component 10-12 to be protected from penetration of the protective coating 2 is dependent at least on the type of protective coating 2 to be applied, the coating method, the component 10-12 to be protected, the materials used, etc., while if need be further criteria, to be defined, may also be used. Providing the edge allows the distance of the coating exclusion region 30 from the component 10-12 to be reduced in size, with the result that structural elements that are arranged alongside the component and are to be covered by the protective coating 2 can be arranged closer to the component 10-12. The edge also makes it possible for structural elements that are arranged close to the component 10-12 to be covered with the protective coating 2 in the first place. This was sometimes not possible with the previous methods, or was inadvisable because the risk of the protective coating 2 penetrating into the coating exclusion region 30 of the component 10-12 and causing damage there was too high.

Depending on the component loading of the printed circuit board 1, the solder resist coating 3 and/or copper layer on the upper side and/or underside of the printed circuit board 1 may be removed.

Shown in FIG. 5 is a flow diagram of the method according to one embodiment of the present invention in which, in a preliminary step or initial step SO, a coating barrier 31 is set up around coating barrier regions 30, into which the protective coating 2 to be applied in the subsequent step 51 must not penetrate, in the form of an edge which is produced by taking back the solder resist coating 3 and/or taking back the copper layer of the printed circuit board 1.

To summarize, this means that the present invention has at least the following advantages. A reduction of the residual contamination requirements for all further components and also for production processes is possible. This brings about a massive cost saving. Using a standard SMD soldering process or other standard types of fastening means that no further requirements have to be met to obtain approval. The described method also allows the number of rejects in production to be minimized.

The proposed method and the printed circuit board 1 produced by it are advantageously used in the case of inverters in the area of electromobility, that is to say for controlling an electric drive or some other electric machine, but also other applications in which components of the printed circuit board 1 must be protected from being penetrated by protective coating 2.

### Reference Numbers

1 Printed circuit board

2 Protective coating

3 Solder resist coating

10 Component (electrical component)

11 Component (through-openings)

12 Component (production bearing surface)

30 Coating exclusion region

31 Coating barrier

1. A method for protecting components of a printed circuit board, the method comprising:
setting up a coating barrier in the form of an edge around coating exclusion regions of the printed circuit board, into which a protective coating does not penetrate; and
providing the printed circuit board with the protective coating at specified regions thereof.

2. The method according to claim 1, further comprising:
producing the coating barrier by taking back a solder resist coating and/or taking back a copper layer of the printed circuit board.

3. The method according to claim 1, further comprising:
producing the coating barrier on an upper side and/or an underside of the printed circuit board.

4. The method according to claim 2, further comprising:
producing the coating barrier on an upper side and/or an underside of the printed circuit board.

5. The method according to claim 1, wherein the coating exclusion regions are specified regions around at least one of electronic components, connectors, pins, screwing areas, through-openings, and/or production bearing surfaces.

6. The method according to claim 2, wherein the coating exclusion regions are specified regions around at least one of electronic components, connectors, pins, screwing areas, through-openings, and/or production bearing surfaces.

7. The method according to claim 3, wherein the coating exclusion regions are specified regions around at least one of electronic components, connectors, pins, screwing areas, through-openings, and/or production bearing surfaces.

8. A printed circuit board, comprising:
a plurality of components; and
a protective coating at specified regions of the printed circuit board,
wherein the printed circuit board is produced by a method comprising:
setting up a coating barrier in the form of an edge around coating exclusion regions of the printed circuit board, into which the protective coating does not penetrate; and
providing the printed circuit board with the protective coating at the specified regions thereof.

9. The printed circuit board according to claim 8, wherein the printed circuit board is produced by the method further comprising:
producing the coating barrier by taking back a solder resist coating and/or taking back a copper layer of the printed circuit board.

10. The printed circuit board according to claim 8, wherein the printed circuit board is produced by the method further comprising:
producing the coating barrier on an upper side and/or an underside of the printed circuit board.

11. The printed circuit board according to claim 8, wherein the coating exclusion regions are specified regions around at least one of electronic components, connectors, pins, screwing areas, through-openings, and/or production bearing surfaces.

12. An inverter comprising the printed circuit board according to claim 8.

13. An electronics module for controlling an electric drive of a vehicle, wherein the electronics module comprises the inverter according to claim 12.

14. An electric drive of a vehicle comprising the electronics module according to claim 13.

15. A vehicle comprising the electric drive according to claim 14.
